(19) United States
(12) Patent Application Publication
(10) Pub. No.: US 2010/0244681 A1
(43) Pub. Date: Sep. 30, 2010

(54) EL DEVICE, LIGHT-SENSITIVE MATERIAL FOR FORMING CONDUCTIVE FILM, AND CONDUCTIVE FILM

(75) Inventor: Tsukasa TOKUNAGA, Minami-ashigara-shi (JP)

Correspondence Address: YOUNG & THOMPSON, 209 Madison Street, Suite 500, Alexandria, VA, 22314, US

(73) Assignee: FUJIFILM CORPORATION, Tokyo (JP)

(21) Appl. No.: 12/749,956

(22) Filed: Mar. 30, 2010

(30) Foreign Application Priority Data
Mar. 30, 2009 (JP) 2009-083222

(51) Int. Cl. H05B 33/02; H05K 1/00; B32B 5/16

(52) U.S. Cl. 313/506; 174/250; 428/341

(57) ABSTRACT

An EL device, comprising:
a support,
a conductive layer with a mesh pattern,
a phosphor layer,
a reflection insulating layer, and
a back electrode;
   wherein the conductive layer, the phosphor layer, the reflection insulating layer and the back electrode are provided on the support in this order, and
   wherein a width X (μm) of an opening portion of the mesh pattern of the conductive layer and a surface resistance Y (Ω/□) of the opening portion of the mesh pattern of the conductive layer meet the following formulae (a) and (b).

50≦X≦7000 (a)

10⁵≦Y≦(5×10²³)×X^{-4.02} (b)

### FIELD OF THE INVENTION

The present invention relate to an EL device, a light-sensitive material for forming a conductive film, and a conductive film.

### BACKGROUND OF THE INVENTION

In recent years, conductive films obtained by various production methods have been investigated (see, for example, JP-A-2000-13088 (“JP-A” means unexamined published Japanese patent application), JP-A-10-340629, JP-A-10-41682, JP-B-42-23746 (“JP-B” means examined Japanese patent publication), and JP-A-2006-228469). Among these conductive films, there are silver salt-basis conductive films produced by a method in which a silver halide emulsion layer is coated and then pattern-exposed so that a pattern shape having a conductive portion of silver for providing conductivity and an opening portion for ensuring transparency can be formed (see, for example, JP-A-2004-221564, JP-A-2004-221565, JP-A-2007-95408, and JP-A-2006-332459).

### SUMMARY OF THE INVENTION

The present invention resides in an EL device comprising a support, and a conductive layer with a mesh pattern, a phosphor layer, a reflection insulating layer and a back electrode provided on the support in this order, wherein a width X (μm) of an opening portion of the mesh pattern of the conductive layer and a surface resistance Y (Ω/□) of the opening portion of the mesh pattern of the conductive layer meet the following formulae (a) and (b):

50≦X≦7000 (a)

10⁵≦Y≦(5×10²³)×X^{-4.02} (b)

Further, the present invention recides in a conductive film comprising a support and a conductive layer with a mesh pattern provided on the support, wherein a width X (μm) of an opening portion of the mesh pattern of the conductive layer and a surface resistance Y (Ω/□) of the opening portion of the mesh pattern of the conductive layer meet the above formulae (a) and (b).

Further, the present invention recides in a light-sensitive material for forming a conductive film comprising a support and a silver salt-containing emulsion layer on the support, wherein the silver salt-containing emulsion layer or any other layer at the same side as the silver salt-containing emulsion layer contains conductive fine particles and a binder, and a content of the binder in the layer is from 0.05 to 0.5 g/m².

Other and further features and advantages of the invention will appear more fully from the following description, taking the accompanying drawing into consideration.

### BRIEF DESCRIPTION OF THE DRAWINGS

FIG. 1 is a cross sectional view of an inorganic EL device (element) that is one preferable embodiment of the present invention.

FIG. 2 is an enlarged cross sectional view of a conductive film (transparent electrode) of the inorganic EL device shown in FIG. 1.

FIG. 3 is a graph showing a relation between the binder content in the layer containing the conductive fine particle and luminance (Example 1).

FIG. 4 is a graph showing a relation between the mesh pitch and luminance (Example 2).

FIG. 5 is a graph showing a relation between the surface resistance of the layer containing conductive fine particle (an opening portion of the mesh pattern) and luminance (Example 3).

FIG. 6 is a graph showing a relation between the width of the opening portion of the mesh pattern and the surface resistance of the opening portion of the mesh pattern (Example 3).

### DETAILED DESCRIPTION OF THE INVENTION

About the silver salt-basis conductive film, various usages have been investigated, and the inventors of the present invention have been researching with paying attention to the use thereof as a planar electrode of an inorganic EL. The inorganic EL device may be obtained, for example, by sticking an integrated member of a phosphor layer, a reflection insulating layer and a back electrode on a conductive film (transparent electrode), or by printing (coating) a phosphor layer, a reflection insulating layer, a back electrode and an insulating layer in this order on a conductive film. However, inorganic EL devices produced by using the silver salt-basis conductive film are inferior in terms of luminance to those produced by using indium tin oxide (ITO) as a conductive film.

According to the present invention, there is provided the following means:

(1) An EL device, comprising:

a support,

a conductive layer with a mesh pattern,

a phosphor layer,

a reflection insulating layer, and

a back electrode;

wherein the conductive layer, the phosphor layer, the reflection insulating layer and the back electrode are provided on the support in this order, and
wherein a width X (μm) of an opening portion of the mesh pattern of the conductive layer and a surface resistance Y (Ω/□) of the opening portion of the mesh pattern of the conductive layer meet the following formulae (a) and (b).

50≦X≦7000 (a)

10⁵≦Y≦(5×10²³)×X^{-4.02} (b)

(2) The EL device described in the above item (1), wherein the width X of an opening portion of the mesh pattern of the conductive layer is from 100 to 5000 μm.
(3) The EL device described in the above item (1) or (2), wherein the surface resistance Y of the opening portion of the mesh pattern of the conductive layer is from 10⁶ to 10¹⁵Ω/□.
(4) The EL device described in any one of the above items (1) to (3), wherein the opening portion of the mesh pattern of the conductive layer contains conductive fine particles.
(5) The EL device described in the above item (4), wherein the conductive fine particles are antimony-doped tin oxide.
(6) The EL device described in the above item (4) or (5), wherein the opening portion of the mesh pattern of the conductive layer contains conductive fine particles and a binder in a ratio by mass of 1/33 to 5/1.
(7) The EL device described in the above item (6), wherein the opening portion of the mesh pattern of the conductive layer contains the conductive fine particles and the binder in a ratio by mass of 1/3 to 5/1.
(8) A conductive film, comprising:

a support, and

a conductive layer with a mesh pattern provided on the support;

wherein a width X (μm) of an opening portion of the mesh pattern of the conductive layer and a surface resistance Y (Ω/□) of the opening portion of the mesh pattern of the conductive layer meet the following formulae (a) and (b).

50≦X≦7000 (a)

10⁵≦Y≦(5×10²³)×X^{-4.02} (b)

(9) A light-sensitive material for forming a conductive film, comprising:

a support, and

a silver salt-containing emulsion layer on the support;

wherein at least one of the silver salt-containing emulsion layer and any other layers at the silver salt-containing emulsion layer side contains conductive fine particles and a binder, and
wherein a content of the binder in the layer containing conductive fine particles and a binder is from 0.05 to 0.5 g/m².
(10) The light-sensitive material for forming a conductive film described in the above item (9), wherein the content of the binder is from 0.05 to 0.2 g/m².
(11) The light-sensitive material for forming a conductive film described in the above item (9) or (10), wherein a content of the conductive fine particles is from 0.05 to 1 g/m².
(12) The light-sensitive material for forming a conductive film described in the above item (11), wherein the content of the conductive fine particles is from 0.1 to 5 g/m².
(13) The light-sensitive material for forming a conductive film described in any one of the above items (9) to (12), wherein colloidal silica is contained in an amount of 0.05 to 0.5 g/m² in the at least one of the silver salt-containing emulsion layer and any other layers at the silver salt-containing emulsion layer side.
(14) A conductive film, comprising a conductive portion formed by subjecting the light-sensitive material described in any one of the above items (9) to (13) to pattern exposure and developing process.

In the invention, the “silver salt-containing emulsion layer side (of the support)” or the conductive layer side denotes a support side opposite to the back face side of the support, i.e., the support side on which at least silver salt-containing emulsion layer or conductive layer is coated.

The light-sensitive material for forming a conductive film of the present invention has a silver salt-containing emulsion layer provided on a support, and at least one of the silver salt-containing emulsion layer and any other layers at the silver salt-containing emulsion layer side contains conductive fine particles and a binder, and the content of the binder in the layer (the conductive fine particle-containing layer) is from 0.05 to 0.5 g/m². As for the light-sensitive material for forming a conductive film of the present invention, for example, an embodiment having substantially only a silver salt-containing emulsion layer on a transparent support, and an embodiment having a silver salt-containing emulsion layer and conductive fine particles-containing layer on a transparent support are considered. In the case of the embodiment in which substantially only a silver salt-containing emulsion layer is provided on the support, the conductive fine particles and the binder are contained in the silver salt-containing emulsion layer, and as a result, the silver salt-containing emulsion layer is a conductive fine particle-containing layer.

About each of the layers of the light-sensitive material for forming a conductive film of the invention, the structure thereof will be described in detail hereinafter.

### [Support]

A support to be employed for the light-sensitive material for forming a conductive film of the present invention can be transparent, for example, a plastic film, a plastic plate or a glass plate.

The support is preferably a plastic film or a plastic plate having a melting point of about 290° C. or lower, such as polyethyleneterephthalate (PET) (melting point: 258° C.), polyethylenenaphthalate (PEN) (melting point: 269° C.), polyethylene (PE) (melting point: 135° C.), polypropylene (PP) (melting point: 163° C.), polystyrene (melting point: 230° C.), polyvinyl chloride (melting point: 180° C.), polyvinylidene chloride (melting point: 212° C.), or triacetyl cellulose (TAC) (melting point: 290° C.). PET is particularly preferred for the support from the viewpoint of light transmittance and workability.

It is preferred that the above support has a transmittance in the entire visible region of 70% to 100%, more preferably 85% to 100%, and particularly preferably 90% to 100%. Further, the support may be colored to an extent not hindering the objects of the present invention.

### [Silver Salt-Containing Emulsion Layer]

The light-sensitive material for forming a conductive film of the present invention has an emulsion layer containing a silver salt as a photosensor (silver salt-containing photosensitive layer) on the support. The silver salt-containing emulsion layer (silver salt-containing photosensitive layer) is subjected to exposure and developing process, thereby forming a conductive layer. The silver salt-containing light-sensitive layer may contain an additive such as a solvent and a dye, in addition to the silver salt and the binder. The silver salt-containing light-sensitive layer is subjected to exposure using a specifically shaped mesh pattern and developing process, thereby forming first conductive layer. The first conductive layer in the present invention is preferably a layer having a mesh-like formed conductive portion and an opening portion other than the conductive portion. The emulsion layer may be composed of a single layer or two or more layers. The thickness of the emulsion layer is preferably 0.1 μm to 10 μm, and more preferably 0.1 μm to 5 μm.

In the light-sensitive material, the silver salt-containing emulsion layer is substantially laid as the topmost layer. The term “the silver salt-containing emulsion layer is substantially laid as the topmost layer” means not only a case where the silver salt-containing emulsion layer is actually laid as the topmost layer, but also a case where a layer(s) having total film thickness of 0.5 μm or less is laid on the silver salt-containing emulsion layer. The total film thickness of the layer(s) laid on the silver salt-containing emulsion layer is preferably 0.2 μm or less.

### (Silver Salt)

Examples of the silver salt used in the present invention include an inorganic-silver salt such as a silver halide, and an organic-silver salt such as silver acetate. In the present invention, it is preferable to employ a silver halide superior in a property as a light-sensor, and technologies of a silver salt photographic film, a photographic paper, a lithographic film, and an emulsion mask for a photomask relating to a silver halide are applicable also in the present invention. The amount of the silver salt to be coated in the silver salt-containing emulsion layer is not particularly limited, and it is preferably from 0.1 to 40 g/m², more preferably from 0.5 to 25 g/m², further preferably from 0.5 to 10 g/m², and particularly preferably 4 to 8.5 g/m² in terms of silver.

The silver halide emulsion to be employed in the present invention may contain a metal belonging to the group VIII or VIIB of the periodic table. Particularly for attaining a high contrast and a low fog level, it is preferable to contain a rhodium compound, an iridium compound, a ruthenium compound, an iron compound, an osmium compound or the like. Such a compound can be a compound having various ligands.

Further, for attaining a high sensitivity, there is advantageously employed a doping with a hexacyano metal complex such as K₄[Fe(CN)₆], K₄[Ru(CN)₆], or K₃[Cr(CN)₆].

The rhodium compound can be a water-soluble rhodium compound. Examples of the water-soluble rhodium compound include a rhodium (III) halide compound, a hexachlororhodium (III) complex salt, a pentachloroaquorhodium complex salt, a tetrachlorodiaquorhodium complex salt, a hexabromorhodium (III) complex salt, a hexaamminerhodium (III) complex salt, a trisalatorhodium (III) complex salt, and K₃[Rh₂Br₉].

Examples of the iridium compound include a hexachloroiridium complex salt such as K₂[IrCl₆] and K₃[IrCl₆], a hexabromoiridium complex salt, a hexaammineiridium complex salt, and a pentachloronitrosyliridium complex salt.

In production of the silver halide emulsion used in the present invention, it is preferable that washing and desalting are carried out without using an anionic precipitation agent during the production process. For the purpose that the washing and desalting are carried out according to a method in which an emulsion is precipitated only by pH adjustment in the absence of an anionic precipitation agent and a supernatant is removed, it is preferable to use a chemically modified gelatin as a dispersant. When a gelatin in which a positively charged amino group has been changed to an uncharged or negatively charged one, is used as a dispersant, it becomes possible to precipitate an emulsion only by reducing pH, and an anionic precipitation agent is not needed for precipitating the emulsion. Examples of the thus-modified gelatin include acetylated, deaminated, benzoylated, dinitrophenylated, trinitrophenylated, carbamylated, phenylcarbamylated, succinylated, succinated or phthalated gelatin. Among these gelatins, it is preferable to use phthalated gelatin. When the phthalated gelatin is used, both conductivity and condition of coating surface can be improved.

### (Binder)

In the emulsion layer, a binder is used to disperse the silver salt particles evenly and to aid the adhesion between the emulsion layer and the support. In the present invention, although both water-insoluble polymer and water-soluble polymer may be used as the binder, it is preferable to use a water-soluble polymer.

Examples of the binder include gelatin, polyvinyl alcohol (PVA), polyvinyl pyrrolidone (PVP), polysaccharides such as starch, cellulose and derivatives thereof, polyethylene oxide, polysaccharide, polyvinyl amine, chitosan, polylysine, polyacrylic acid, polyalginic acid, polyhyaluronic acid, and carboxycellulose. They have a neutral, anionic or cationic property depending on the ionic property of the functional group. In the present invention, it is particularly preferable to use gelatin.

The amount of the binder contained in the emulsion layer is not particularly restricted, and can be suitably selected within a range of meeting the dispersibility and the adhesion. As for the binder content in the emulsion layer, the ratio by volume of Ag to the binder is preferably 1/10 or more, more preferably 1/4 or more, further preferably 1/2 or more. In addition, the ratio by volume of Ag to the binder is particularly preferably 1/2 to 10/1, the most preferably 1/2 to 5/1.

### (Solvent)

A solvent to be employed in forming the emulsion layer is not particularly limited, and can be, for example, water, an organic solvent (for example, alcohols such as methanol, ketones such as acetone, amides such as formamide, sulfoxides such as dimethyl sulfoxide, esters such as ethyl acetate, or ethers), an ionic liquid or a mixture thereof.

The content of the solvent to be used in the emulsion layer of the present invention is preferably in the range of 30 to 90% by mass, more preferably in the range of 50 to 80% by mass, with respect to the total mass of the silver salt, the binder and the like contained in the emulsion layer.

Various additives to be employed in the present invention are not particularly limited, and any additive can be employed advantageously. Examples thereof include a thickener, an antioxidant, a matting agent, a lubricant, an antistatic agent, a nucleating agent, a spectral sensitizing dye, a surfactant, an antifog agent, a hardener, and a black-spot inhibitor. A compound having a high dielectric constant may be added. In order to make the surface hydrophobic, a hydrophobic group(s) may be introduced into the binder, or a hydrophobic compound may be added into the binder.

### (Conductive Fine Particles and Binder)

In the light-sensitive material for forming a conductive film of the present invention, at least one of the silver salt-containing emulsion layer and any other layers at the silver salt-containing emulsion layer side contains conductive fine particles and a binder. When the layer containing the conductive fine particles is the any other layer(s) at the silver salt-containing emulsion layer side, the layer(s) is not particularly limited in position as far as the layer satisfies the requirement that the layer has electroconductivity to a conductive layer after a conductive material is produced. Particularly, it is preferable that the layer containing conductive fine particles and a binder is disposed on the silver salt-containing emulsion layer.

The content of the binder in the conductive fine particle-containing layer is from 0.05 to 0.5 g/m², preferably from 0.05 to 0.3 g/m², and more preferably from 0.05 to 0.2 g/m². In the case of a large content of the binder, the surface resistance of the conductive fine particle-containing layer tends not to sufficiently decrease even though the content of conductive fine particles increases. It is possible to sufficiently decrease the surface resistance by controlling the content of the binder within the above-described range without using more than necessary amount of the conductive fine particles. In contrast, in the case of too small content of the binder, there is a possibility that conductive fine particles fall out during production process, which is not favorable to process management. Further, when the content of the binder is much more than enough amount, luminance decreases, which is not favorable. On the other hand, when the content of the binder is much less than enough amount, dispersion of conductive fine particles becomes unstable, which is not favorable.

The content of the conductive fine particles in the conductive fine particle-containing layer is preferably from 0.05 to 1 g/m², more preferably from 0.1 to 0.5 g/m², and more preferably from 0.2 to 0.45 g/m². When the content of the conductive fine particles is too large, dispersion of conductive fine particles becomes unstable, which is not favorable. On the other hand, when the content of the binder is too small, in the conductive film having a mesh-patterned conductive portion formed by subjecting the above-described light-sensitive material to a pattern exposure and a developing process, an opening portion of the conductive film may not emit light in some times, which is not favorable. The ratio by mass of the conductive fine particles to the binder (the conductive fine particles/the binder) is preferably from 1/33 to 5/1, more preferably from 1/3 to 5/1.

Examples of the conductive fine particles to be employed in the present invention include particles of metal oxide such as SnO₂, ZnO, TiO₂, Al₂O₃, In₂O₃, MgO, BaO and MoO₃; particles of a composite oxide thereof; and particles of a metal oxide obtained by incorporating a different atom into such a metal oxide. Preferred examples of the metal oxide include SnO₂, ZnO, TiO₂, Al₂O₃, In₂O₃, and MgO; and SnO₂ is particularly preferred. SnO₂ particles are preferably SnO₂ particles doped with antimony, particularly preferably SnO₂ particles doped with antimony in an amount of 0.2 to 2.0% by mol. The shape of the conductive fine particles to be employed in the present invention is not particularly limited, and examples thereof include granular and needle shapes. The particle diameter of the conductive fine particles is preferably from 0.005 to 0.12 μm. The lower limit of the particle diameter is more preferably 0.008 μm, and more preferably 0.01 μm. The upper limit of the particle diameter is more preferably 0.08 μm, and more preferably 0.05 μm. When the particle diameter meets the above requirement, there can be formed a conductive layer excellent in transparency and even in conductivity in the in-plane direction.

The lower limit of the powder resistivity of the conductive fine particles (powder under the pressure of 9.8-MPa) is preferably 0.8 Ωcm, more preferably 1 Ωcm, and further preferably 4 Ωcm. The upper limit of the powder resistivity of the conductive fine particles (powder under the pressure of 9.8-MPa) is preferably 35 Ωcm, more preferably 20 Ωcm, and further preferably 10 Ωcm. When the powder resistivity meets the above requirement, a conductive layer even in conductivity in the in-plane direction can be formed.

The specific surface area (according to a simple BET method) is preferably from 60 to 120 m²/g, more preferably from 70 to 100 m²/g. Conductive fine particles satisfying all of the above-mentioned preferred requirements are particularly preferred.

When the conductive fine particles are spherical particles, the average (primary) particle diameter is preferably from 0.005 to 0.12 μm, more preferably from 0.008 to 0.05 μm, and further preferably 0.01 to 0.03 μm. The powder resistivity is preferably from 0.8 to 7 Ωcm, and more preferably from 1 to 5 Ωcm.

When the particles are needle-form particles, the average axial length of their long axes is preferably from 0.2 to 20 μm and that of their short axes is from 0.01 to 0.02 μm. The powder resistivity thereof is preferably from 3 to 35 Ωcm, and more preferably from 5 to 30 Ωcm.

When the conductive fine particles and the binder are contained in the silver salt-containing emulsion layer, the coating amount of the conductive fine particles is preferably from 0.05 to 0.9 g/m², more preferably from 0.1 to 0.6 g/m², further preferably from 0.1 to 0.5 g/m², and particularly preferably from 0.2 to 0.4 g/m².

In the present invention, it is allowable to lay an optional layer other than the silver-salt-containing emulsion layer, and incorporate the conductive fine particles and the binder into the optional layer. The optional layer may be an upper layer or lower layer with respect to the silver-salt-containing emulsion layer. It is also preferred to incorporate the conductive fine particles and the binder into a layer adjacent to the silver-salt-containing emulsion layer The term “upper layer” means a layer which is nearer to the topmost surface layer (or the topmost layer) and is farther from the support than the emulsion layer, and the term “lower layer” means a layer nearer to the support than the emulsion layer.

When the layer containing the conductive fine particles and the binder is provided in addition to the silver-salt-containing emulsion layer (for example, as an upper layer with respect to the silver-salt-containing emulsion layer), the coating amount of the conductive fine particles is preferably from 0.1 to 0.6 g/m², more preferably from 0.1 to 0.5 g/m², and further preferably from 0.2 to 0.4 g/m². When the layer containing the conductive fine particles and the binder is a lower layer (such as an undercoating layer), the coating amount of the conductive fine particles is preferably from 0.1 to 0.6 g/m², more preferably from 0.1 to 0.5 g/m², and further preferably from 0.16 to 0.4 g/m². In these case, the content of the binder in the conductive fine g/m², preferably from 0.05 to 0.3 g/m², and more preferably from 0.05 to 0.2 g/m².

In the present invention, an embodiment in which a silver salt-containing emulsion layer, a conductive fine particle-containing layer, and a protective layer are provided on a support is preferable. The protective layer is formed with a coating liquid containing a binder (preferably gelatin) and a solvent. In this embodiment, a total content of the binder contained in both conductive fine particle-containing layer and protective layer is preferably set in a range of 0.05 to 0.5 g/m², more preferably from 0.05 to 0.3 g/m², and further preferably from 0.05 to 0.2 g/m². When the content of the binder in the protective layer is too large, conductivity of the conductive fine particle-containing layer and a layer adjacent thereto may not be sufficient and, as a result, a predetermined effect may not be obtained.

When the coating amount of the conductive fine particles is too large, the transparency becomes insufficient for practical use, and the resultant conductive film tends to be unsuitable for a transparent conductive film. Furthermore, when the coating amount of the conductive fine particles is too large, it is not easy to disperse the conductive fine particles in the coating process, and production failures tend to increase. When the coating amount is too small, the in-plane electric characteristics become insufficient, and when the resultant film is used for an EL element, the luminance tends to become insufficient for practical use.

It is preferable that the position of the layer in which conductive fine particles are contained is an upper layer of the silver salt-containing emulsion layer. Luminance of EL device can be increased by this configuration. It is assumed that this effect is attributed to the function by which a content of the binder in the layer closer to the phosphor layer affects permittivity of voltage that is applied to the phosphor. In other words, even though the EL device that has been produced by forming a conductive fine particle-containing layer at the position of an emulsion layer or a layer lower to the emulsion layer, and then forming a phosphor layer above these layers emits light, luminance of EL device is reduced to some extent by the presence of a binder in the silver salt-containing emulsion layer and protective layer each applied above the conductive fine particle-containing layer.

The binder that is contained in the conductive fine particle-containing layer has a function to make conductive fine particles adhere to the support. As such binder, a water-soluble polymer is preferably used. As the binder, for example, it is possible to use the same binder as those used in the emulsion layer.

### [Other Layer Structures]

A protective layer may be formed on the emulsion layer. In the present invention, the “protective layer” means a layer made from a binder such as gelatin and a polymer, and is formed on the emulsion layer having light-sensitivity, for the purposes of preventing scratches and improving mechanical characteristics. The thickness of the protective layer is preferably 0.2 μm or less. A coating method and a forming method of the protective layer are not particularly limited, and an ordinary coating method and forming method can be appropriately selected. Below the emulsion layer, for example, an undercoating layer may be laid.

### [Conductive Film]

The conductive film of the present invention has a conductive layer with a mesh-pattern provided on a support (preferably transparent support), wherein a width X (μm) of an opening portion of the mesh pattern of the conductive layer and a surface resistance Y (Ω/□) of the opening portion of the mesh pattern of the conductive layer meet the following formulae (a) and (b). Further, the conductive film satisfies preferably the following formula (b1), more preferably the following formula (b2).

50≦X≦7000 (a)

10⁵≦Y≦(5×10²³)×X^{-4.02} (b)

10⁵≦Y≦(1×10²³)×X^{-4.02} (b)

10⁵≦Y≦(3×10²²)×X^{-4.25} (b)

The conductive film used in the present invention is necessary to meet the above-described conditions in terms of a surface resistance of the opening portion of the mesh pattern. It is preferable that a conductive film is obtained by subjecting the above-described light-sensitive material for forming a conductive film to pattern exposure and developing process. However, the conductive film used in the present invention is not limited to this type of conductive film.

With respect to the conductive film used in the present invention, when the conductive layer, and/or any other layer(s) at the conductive layer side contains conductive fine particles and a binder, examples of the conductive film (first conductive film) include a conductive film obtained by subjecting the aforementioned light-sensitive material for forming a conductive film to pattern exposure and developing process, a layer having a copper foil mesh pattern, and a layer having a mesh pattern formed by a printing method. In addition to the first conductive film and the second conductive film (the any other layer(s) at the conductive layer side containing conductive fine particles and a binder, for example, the protective layer and the undercoat layer), further a layer containing conductive fine particles different from the conductive fine particles contained in the second conductive film, an ITO layer and a conductive polymer-containing layer may be disposed.

The first conductive layer and the second conductive layer in the conductive film of the present invention preferably satisfy relationships described below. When the relationships are satisfied, the in-plane electric characteristics of the conductive film become evener. Thus, when the film is made into an inorganic EL device, a sufficient luminance can be obtained in the whole of its plane.

(1) The surface resistivity of the first conductive layer is smaller than that of the second conductive layer.
(2) The surface resistivity of the first conductive layer is 1,000 Ω/sq or less (and 0.01 Ω/sq or more), and that of the second conductive layer is 1,000 Ω/sq or more (and 1×10¹⁴ Ω/sq or less).

The upper limit of the surface resistivity of the first conductive layer is more preferably 150 Ω/sq. The lower limit of the surface resistivity of the first conductive layer is more preferably 0.1 Ω/sq, and particularly preferably 1 Ω/sq.

The upper limit of the surface resistivity of the second conductive layer (conductive fine particle-containing layer) is more preferably 1×10¹³ Ω/sq. The lower limit of the surface resistivity of the second conductive layer is preferably 1×10⁸ Ω/sq, and particularly preferably 1×10⁹ Ω/sq.

It is preferable that silica is contained in an amount of 0.05 to 0.5 g/m² in the conductive layer used in the present invention. It is preferable that the content of the silica is 0.16 g/m² or more, and further preferably 0.24 g/m² or more. It is preferable that the content of the silica is 0.5 g/m² or less, and further preferably 0.4 g/m² or less. If the content of the silica is excessive, dispersion of silica may become difficult in a production process, or surface condition may become worse.

As for the silica, it is preferable to use silica in a colloid (colloidal silica). The colloidal silica means a colloid of fine particles of silicic anhydride having an average particle size of 1 nm or more and 1 μm or less, and those described in JP-A-53-112732, JP-B-57-9051 and JP-B-57-51653. Such colloidal silica can be prepared by a sol-gel method and used, and commercially available products can also be used.

In the case where colloidal silica is prepared by a sol-gel method, it can be prepared by referring to, for example, Werner Stober, et al., “J. Colloid and Interface Sci.”, 26, p. 62-69 (1968); Ricky D. Badley, et al., “Langmuir”, 6, p. 792-801 (1990); and “Skikizai Kyokaishi (Journal of the Japan Society of Colour Material)”, 61[9], p. 488-493 (1988).

In the case where a commercially available product is used, SNOWTEX-XL (average particle size: 40 to 60 nm), SNOWTEX-YL (average particle size: 50 to 80 nm), SNOWTEX-ZL (average particle size: 70 to 100 nm), PST-2 (average particle size: 210 nm), MP-3020 (average particle size: 328 nm), SNOWTEX 20 (average particle size: 10 to 20 nm, SiO₂/Na₂O>57), SNOWTEX 30 (average particle size: 10 to 20 nm, SiO₂/Na₂O>50), SNOWTEX C (average particle size: 10 to 20 nm, SiO₂/Na₂O >100), and SNOWTEX O (average particle size: 10 to 20 nm, SiO₂/Na₂O>500), all of them are trade name and manufactured by Nissan Chemical Industries, Ltd., and the like can be preferably used (the term “SiO₂/Na₂O” as referred to herein is a content mass ratio of silicon dioxide to sodium hydroxide as expressed by converting sodium hydroxide to Na₂O and is described in a brochure). In the case where a commercially available product is used, SNOWTEX-YL, SNOWTEX-ZL, PST-2, MP-3020 and SNOWTEX C are particularly preferable.

Though a major component of the colloidal silica is silicon dioxide, alumina, sodium aluminate or the like may be contained as a minor component; and/or an inorganic base such as sodium hydroxide, potassium hydroxide, lithium hydroxide and ammonia, or an organic base such as tetramethylammonium may be contained as a stabilizer.

Colloidal silica having a long and narrow shape of 1 to 50 nm in thickness and 10 to 1,000 nm in length as described in JP-A-10-268464; and a composite particle of colloidal silica and an organic polymer as described in JP-A-9-218488 or JP-A-10-111544 can also be preferably used.

The following will describe, in detail, embodiments of the conductive film obtained by pattern-exposing the light-sensitive material for forming a conductive film of the present invention and then subjecting the exposed material to developing treatment.

Examples of the mesh pattern formed by the pattern-exposure and developing treatment include a lattice pattern, in which straight lines cross each other at right angles, and a wavy lattice pattern, which has at least a curve at the conductive portion between crossing portions. In the present invention, the pitch of mesh pattern of the conductive layer (the total of a line width of the conductive portion and a width of the opening portion) is preferably 250 to 1,000 μm. The line width of the conductive portion is preferably 30 μm or less, more preferably 20 μm or less, and further preferably 15 μm or less. The line width is preferably 1 μm or more, and more preferably 3 μm or more. For example, as for the rectilinear grid pattern, it is preferable that the ratio of line width of the conductive portion/width of opening portion, namely line/space is from 5/995 to 10/595.

The width X (μm) of the opening portion of the mesh pattern of the conductive layer in the present invention is from 50 to 7,000 μm, preferably 100 to 5,000 μm, and more preferably 200 to 2,000 μm.

In the present invention, a transparent conductive layer having higher resistance may be formed by coating a conductive polymer or the like on the conductive layer within a range in which conductive properties are secured.

### [Exposure]

A pattern-exposure of the silver salt-containing emulsion layer can be performed by a planar exposure using a photomask, or by a scanning-exposure with a laser beam. A refractive exposure employing a lens or a reflective exposure employing a reflecting mirror may be employed, and a contact exposure, a proximity exposure, a reduced projection exposure, a reflective projection exposure or the like may be used.

### [Developing Treatment]

After light-exposure is performed on the silver salt-containing emulsion layer, the emulsion layer is further subjected to a developing process. As for the developing process, it is possible to use an ordinary developing technique that is used for a silver salt photographic film, a photographic paper, a lithographic film, an emulsion mask for photomask, or the like.

In the present invention, the aforementioned pattern-exposure and developing treatment are conducted, whereby a conductive portion (metal silver portion) having a mesh pattern is formed in the exposed portion, and also an opening portion (light-transmitting portion) is formed in the unexposed portion.

The developing process of the light-sensitive material may include a fixing process conducted to remove the silver salt in the unexposed portion and attain stabilization. In the fixing process of the light-sensitive material of the present invention, there may be used any technique of the fixing process used for a silver salt photographic film, a photographic paper, a lithographic film, an emulsion mask for photomasks, and the like.

In the case where the silver-salt-containing emulsion layer contains the conductive fine particles, with respect to the thus-obtained conductive film, the conductive fine particles are dispersed in a light transmissible region, from which the silver salt has dropped out, so that a conductive layer having a higher resistivity than the metallic silver region is formed. When any layer(s) other than the silver-salt-containing emulsion layer contains the conductive fine particles, a conductive layer having a light transmissible region wherein the conductive fine particles are dispersed is formed in the same manner. The conductive film is preferably used as a transparent electrode of an EL device. Further, the conductive film of the present invention may be used not only for a transparent electrode of the EL device, but also for various structures in which the transparent electrode is incorporated as an essential component. Examples of the structure equipped with the transparent electrode include light-emitting display devices and electrochromic devices.

### [EL Device]

The EL device of the present invention is described in detail below.

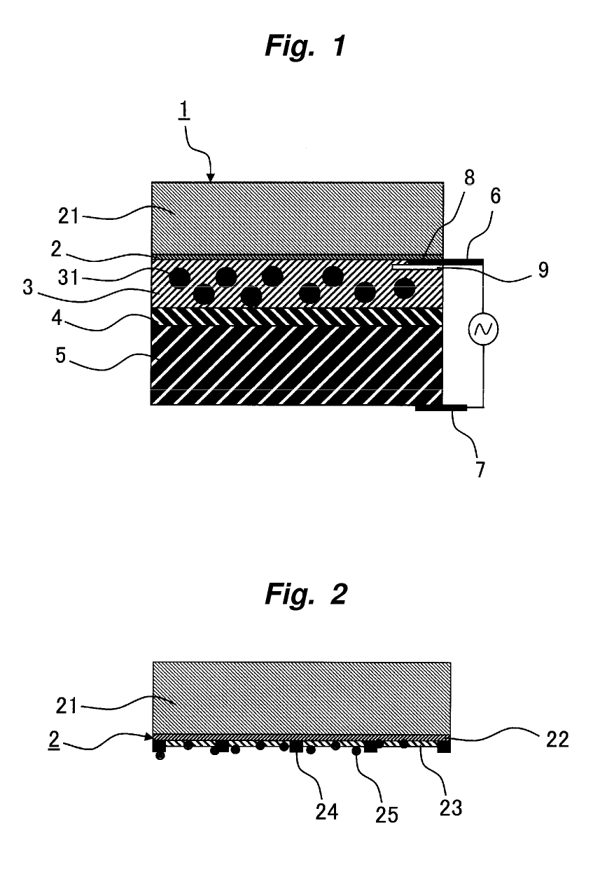

The EL device of the present invention has a construction in which a phosphor layer is sandwiched between a pair of opposed electrodes, and at least one of the electrodes has the above-described conductive film. The EL device may be an organic EL device, or an inorganic EL device. FIG. 1 shows a sectional view of a preferred embodiment of the inorganic EL device of the present invention.

The inorganic EL device 1 that is one preferable embodiment of the present invention has a transparent electrode (the above-described conductive film) 2, a phosphor layer 3, a reflection insulating layer 4 and a back electrode 5 in this order. The phosphor layer 3 is disposed at a conductive layer side of the conductive film. The transparent electrode 2 and the back electrode 5 are electrically connected to each other through electrodes 6 and 7. A silver paste 8 is applied as a supplemental electrode on the electrode 6 that contacts the transparent electrode 2, and an insulating paste 9 is applied at the side of the phosphor layer 3.

The phosphor layer 3, the reflection insulating layer 4 and the back electrode 5 may be provided by printing (coating) these layers on the transparent electrode, or alternatively a device may be formed by sticking them. Herein the expression “provided by printing (coating)” means directly printing (coating) the phosphor layer 3, the reflection insulating layer 4 and the back electrode 5 on the transparent electrode. Further, the expression “sticking” means forming a device by thermal compression bond of the transparent electrode and an integrated member of the phosphor layer 3, the reflection insulating layer 4 and the back electrode 5.

An electric potential difference is applied to phosphor 31 in the phosphor layer 3 by applying voltage to the transparent electrode 2 and the back electrode 5. The electric potential difference becomes emission energy, and a light-emitting state is maintained by continuing to apply the electric potential difference using an AC source.

### [Transparent Electrode]

The above-described transparent conductive film is used as the transparent electrode 2 used in the present invention. An enlarged cross sectional view of a conductive film (transparent electrode) of the inorganic EL device shown in FIG. 1 is shown in FIG. 2. In FIG. 2, the conductive film 2 has, on a transparent support 21, an undercoat layer (Gel layer) 22, a conductive fine particle-containing layer (tin oxide layer), 23 and a silver mesh patterned conductive layer 24. Further, colloidal silica particles 25 are formed in the tin oxide layer 23, and/or the conductive layer 24. As is shown in FIG. 2, it is preferred that conductive fine particles are contained in the opening portion 23 in the mesh pattern of the conductive layer. Further, it is preferred that the opening portion of the mesh pattern of the conductive layer contains the conductive fine particles and the binder in a ratio by mass of 1/33 to 5/1, and more preferably from 1/3 to 5/1.

### [Phosphor Layer]

The phosphor layer (phosphor particle layer) 3 is formed by dispersing phosphor particles 31 in a binder. As the binder, polymers having a comparatively high permittivity, such as cyanoethyl cellulose series resins, and resins such as polyethylene, polypropylene, polystyrene series resins, silicone resin, epoxy resin and vinylidene fluoride resin can be used. The thickness of the phosphor layer 3 is preferably from 1 μm to 50 μm.

The phosphor particles 31 contained in the phosphor layer 3 are, specifically, particles of a semiconductor comprising one or more elements selected from the group consisting of the Group II elements and the Group VI elements and one or more elements selected from the group consisting of the Group III elements and the Group V elements. The elements are selected according to the necessary luminescence wavelength region. As the particles, ZnS, CdS and CaS are preferably used.

The average sphere-equivalent diameter of the phosphor particles 31 is preferably from 0.1 μm to 15 μm. The variation coefficient of the average sphere-equivalent diameter is preferably 35% or less, and more preferably from 5% to 25%. The average sphere-equivalent diameter of these particles can be measured using, for example, LA-500 (trade name, manufactured by HORIBA Ltd.) according to a laser light scattering method, or a coulter counter manufactured by Beckman Coulter Inc.

### [Reflection Insulating Layer]

It is preferable that the inorganic EL device 1 of the present invention has a reflection insulating layer (in some cases, also referred to as a dielectric layer) 4 close to both the phosphor layer 3 and the back electrode 5, and disposed between these layers.

In the dielectric layer 4, any dielectric substances may be used, so long as the substance has high dielectric constant and high insulation properties, and also high dielectric breakdown voltage. These substances are selected from metal oxides and nitrides. For example, BaTiO₃, BaTa₂O₆, or the like may be used. The dielectric layer 4 containing a dielectric substance may be disposed at one side of the phosphor particle layer 3. The dielectric layer 4 is also preferably disposed at both sides of the phosphor particle layer 3.

It is preferable that film formation of the phosphor layer 3 and the dielectric layer 4 is carried out, for example, by coating these layers in accordance with, for example, a spin coating method, a dip coating method, a bar coating method, or a spray coating method, or by screen-printing them.

### [Back Electrode]

In the back electrode 5 from which light is not taken out, any conductive substances may be used. For example, a transparent electrode such as ITO, or an aluminum/carbon electrode may be used, so long as the substance is conductive. Further, the aforementioned conductive film may be used as the back electrode.

### [Sealing/Water Absorption]

It is preferable that the EL device of the present invention has a proper sealing material on the opposite side of the transparent conductive film. It is also preferable that the EL device is processed so that the device can be insulated from influences of moisture and oxygen from the outside environment. When the support itself of the device has sufficient shielding properties, a moisture and oxygen-shielding sheet is covered above the produced device, and then the periphery of the device can be sealed with a curable material such as epoxy resins. Further, a shielding sheet (water-proof sheet) may be provided on both surfaces of a planar device in order to prevent from curing. When the support of the device is water-permeable, it is necessary to provide shielding sheets on both surfaces of the device.

In the EL device of the present invention, the width X (μm) of an opening portion of the mesh pattern of the conductive layer and the surface resistance Y (Ω/□) of the opening portion of the mesh pattern meet the following formulae (a) and (b).

50≦X≦7000 (a)

10⁵≦Y≦(5×10²³)×X^{-4.02} (b)

The width X of the opening portion of the mesh pattern of the conductive layer is preferably from 100 to 5,000 μm. Further, the surface resistance Y of the opening portion of the mesh pattern of the conductive layer is preferably from 10⁶ to 10¹⁵Ω/□.

The EL device of the present invention has luminance equal to or higher than that obtained by using an ITO thin film as a conductive film, and therefore, the EL device of the present invention is excellent in optical properties. Further, the EL device of the present invention has an advantage in such a point that whole area-light emission of the EL device can be performed while luminance is secured in an approximately uniform state, even when the EL device has a big size, such as 30 cm×30 cm size and 30 cm×50 cm size.

### [Voltage and Frequency]

Ordinarily, a dispersion type EL device is driven on AC. Typically, the device is driven using an AC source ranging from 50 Hz to 400 Hz at 100 V.

For the above-mentioned light-sensitive material, the conductive film and the inorganic EL device of the present invention, any appropriate combination of two or more selected from known documents listed up below may be used.

JP-A-2004-221564, JP-A-2004-221565, JP-A-2007-200922, JP-A-2006-352073, WO 2006/001461, JP-A-2007-129205, JP-A-2007-235115, JP-A-2007-207987, JP-A-2006-012935, JP-A-2006-010795, JP-A-2006-228469, JP-A-2006-332459, JP-A-2007-207987, JP-A-2007-226215, WO 2006/088059, JP-A-2006-261315, JP-A-2007-072171, JP-A-2007-102200, JP-A-2006-228473, JP-A-2006-269795, JP-A-2006-267635, JP-A-2006-267627, WO 2006/098333, JP-A-2006-324203, JP-A-2006-228478, JP-A-2006-228836, JP-A-2006-228480, WO 2006/098336, WO 2006/098338, JP-A-2007-009326, JP-A-2006-336057, JP-A-2006-339287, JP-A-2006-336090, JP-A-2006-336099, JP-A-2007-039738, JP-A-2007-039739, JP-A-2007-039740, JP-A-2007-002296, JP-A-2007-084886, JP-A-2007-092146, JP-A-2007-162118, JP-A-2007-200872, JP-A-2007-197809, JP-A-2007-270353, JP-A-2007-308761, JP-A-2006-286410, JP-A-2006-283133, JP-A-2006-283137, JP-A-2006-348351, JP-A-2007-270321, JP-A-2007-270322, WO 2006/098335, JP-A-2007-088218, JP-A-2007-201378, JP-A-2007-335729, WO 2006/098334, JP-A-2007-134439, JP-A-2007-149760, JP-A-2007-208133, JP-A-2007-178915, JP-A-2007-334325, JP-A-2007-310091, JP-A-2007-311646, JP-A-2007-013130, JP-A-2006-339526, JP-A-2007-116137, JP-A-2007-088219, JP-A-2007-207883, JP-A-2007-207893, JP-A-2007-207910, JP-A-2007-013130, WO 2007/001008, JP-A-2005-302508, JP-A-2005-197234, JP-A-2008-218784, JP-A-2008-227350, JP-A-2008-227351, JP-A-2008-244067, JP-A-2008-267814, JP-A-2008-270405, JP-A-2008-277675, JP-A-2008-277676, JP-A-2008-282840, JP-A-2008-283029, JP-A-2008-288305, JP-A-2008-288419, JP-A-2008-300720, JP-A-2008-300721, JP-A-2009-4213, JP-A-2009-10001, JP-A-2009-16526, JP-A-2009-21334, JP-A-2009-26933, JP-A-2008-147507, JP-A-2008-159770, JP-A-2008-159771, JP-A-2008-171568, JP-A-2008-198388, JP-A-2008-218096, JP-A-2008-218264, JP-A-2008-224916, JP-A-2008-235224, JP-A-2008-235467, JP-A-2008-241987, JP-A-2008-251274, JP-A-2008-251275, JP-A-2008-252046, JP-A-2008-277428, and JP-A-2009-21153.

According to the present invention, it is possible to provide an EL device having luminance equal to or more excellent than that obtained by using an ITO thin film as a conductive film, and to provide a light-sensitive material for forming a conductive film of the EL device.

When the light-sensitive material for forming a conductive film of the invention is used, a conductive film having a high conductivity can be produced at low cost, without being subjected to any plating treatment, by exposing the material patternwise to light and then subjecting the exposed material to developing treatment. In particular, a conductive material having a high conductivity and transparency can be produced at low cost.

The EL device provided with a conductive film formed by using the light-sensitive material for forming a conductive film of the present invention has luminance equal to or higher than that obtained by using an ITO thin film as a conductive film, and therefore, the EL device is excellent in optical properties.

The present invention will be described in more detail based on the following examples, but the invention is not intended to be limited thereto.

### EXAMPLES

### Example 1

### Preparation of Emulsion A

### Solution 1:

| | | |
|---|---|---|
| Water | 750 | ml |
| Gelatin (phthalation-treated gelatin) | 8 | g |
| Sodium chloride | 3 | g |
| 1,3-Dimethylimidazolidine-2-thione | 20 | mg |
| Sodium benzenethiosulfonate | 10 | mg |
| Citric acid | 0.7 | g |

### Solution 2:

| | | |
|---|---|---|
| Water | 300 | ml |
| Silver nitrate | 150 | g |

### Solution 3:

| | | |
|---|---|---|
| Water | 300 | ml |
| Sodium chloride | 38 | g |
| Potassium bromide | 32 | g |
| Potassium hexachloroiridate (III) | 5 | ml |
| (0.005% in 20% aqueous KCl solution) | | |
| Ammonium hexachlororhodate | 7 | ml |
| (0.001% in 20% aqueous NaCl solution) | | |

The potassium hexachloroiridate (III) (0.005% in 20% aqueous KCl solution) and ammonium hexachlororhodate (0.001% in 20% aqueous NaCl solution) used in Solution 3 were prepared by dissolving complex powders thereof in a 20% aqueous solution of KCl and a 20% aqueous solution of NaCl, respectively, and heating the solutions at 40° C. for 120 minutes.

To solution 1, while the temperature and the pH of which were kept at 38° C., pH 4.5, solutions 2 and 3 (in amounts corresponding to 90% of the respective solution amounts) were added simultaneously over a period of 20 minutes with being stirred. In this way, nucleus particles of 0.16 μm in size were formed. Subsequently, the following solutions 4 and 5 were added thereto over a period of 8 minutes, and the rests of the solutions 2 and 3 (in amounts corresponding to 10% of the respective solution amounts) were further added thereto over a period of 2 minutes so as to cause the particles to grow up to 0.21 μm in size. Furthermore, 0.15 g of potassium iodide was added thereto, and the resultant was aged for 5 minutes to end the formation of the particles.

### Solution 4:

| | | |
|---|---|---|
| Water | 100 | ml |
| Silver nitrate | 50 | g |

### Solution 5:

| | | |
|---|---|---|
| Water | 100 | ml |
| Sodium chloride | 13 | g |
| Potassium bromide | 11 | g |
| Potassium ferrocyanide | 5 | mg |

Thereafter, washing with water by the flocculation method according to an ordinary method was conducted. Specifically, the temperature was lowered to 35° C., and then pH was reduced using sulfuric acid until silver halide precipitated (precipitation occurred in the pH range of 3.6±0.2).

About 3 L of the supernatant was then removed (first water washing). Further, 3 L of distilled water was added to the mixture, and sulfuric acid was added until silver halide precipitated. Again, 3 L of the supernatant was removed (second water washing). The procedure same as the second water washing was repeated once more (third water washing), and water-washing and desalting steps were thus completed.

The pH and pAg of the emulsion subjected to the washing and desalting were 6.4 and 7.5, respectively. Thereto, 10 mg of sodium benzenethiosulfonate, 3 mg of sodium benzenethiosulfinate, 15 mg of sodium thiosulfate, and 10 mg of chloroauric acid were added, and the mixture was thus subjected to chemical sensitization to obtain the optimal sensitivity at 55° C. Then, 100 mg of 1,3,3a,7-tetrazaindene as a stabilizing agent, and 100 mg of Proxel (trade name, manufactured by ICI Co., Ltd.) as an antiseptic were added. Finally, a silver iodochlorobromide cubic particle emulsion containing 70 mol % of silver chloride and 0.08 mol % of silver iodide and having an average particle diameter of 0.22 μm and variation coefficient of 9% was obtained. The emulsion had finally a pH of 6.4, a pAg of 7.5, an electrical conductivity of 40 μS/m, a density of 1.2×10³ kg/m³, and a viscosity of 60 mPa·s.

### (Preparation of Emulsion Layer Coating Liquid A)

To the above-described Emulsion A, 5.7×10⁻⁴ mol/mol Ag of a sensitizing dye (SD-1) was added so as to carry out spectral sensitization. Furthermore, 3.4×10⁻⁴ mol/mol Ag of KBr and 8.0×10⁻⁴ mol/mol Ag of Compound (Cpd-3) were added thereto and sufficiently mixed.

Subsequently, 1.2×10⁻⁴ mol/mol Ag of 1,3,3a,7-tetrazaindene, 1.2×10⁻² mol/mol Ag of hydroquinone, 3.0×10⁻⁴ mol/mol Ag of citric acid, 90 mg/m² of sodium 2,4-dichloro-6-hydroxy-1,3,5-triazine, 15% by mass relative to the gelatin of colloidal silica having a particle size of 10 μm, 50 m g/m² of aqueous latex (aqL-6), 100 mg/m² of a polyethylacrylate latex, 100 mg/m² of a latex copolymer of methyl acrylate, sodium 2-acrylamide-2-methylpropanesulfonate and 2-acetoxyethyl methacrylate (ratio by mass 88:5:7), 100 mg/m² of a core-shell type latex (core: styrene/butadiene copolymer (ratio by mass 37/63), shell: styrene/2-acetoxyethyl acrylate (ratio by mass 84/16), core/shell ratio=50/50), and a compound (Cpd-7) (4% by mass of relative to the gelatin) were added to the mixture to prepare the emulsion layer coating liquid A. The pH of the coating liquid A was adjusted to 5.6 using citric acid.

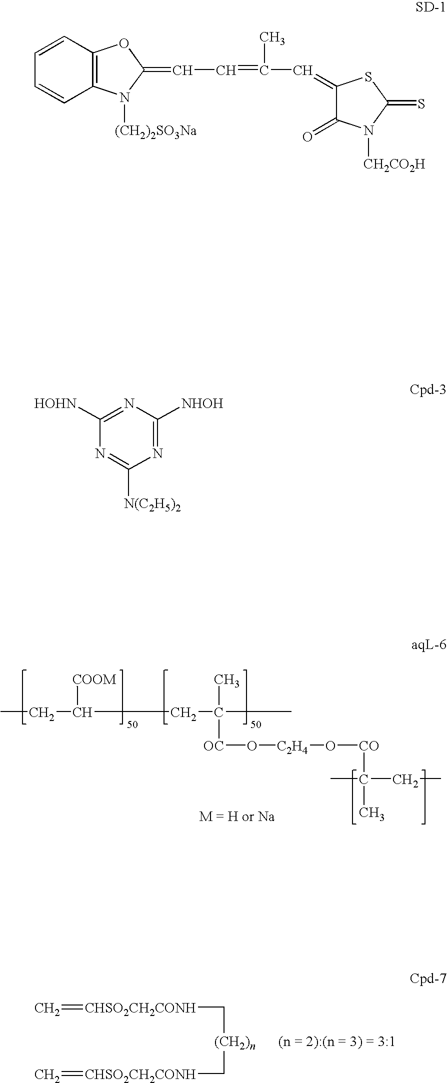

### (Production of Inorganic EL Device Sample A)

On a polyethyleneterephtharate film support, both surfaces of which were provided with a moisture barrier undercoat layer (underlayer) containing vinylidene chloride, a silver halide emulsion layer, a conductive fine particle layer and an adhesion-providing layer were coated in this order, whereby an inorganic EL device sample A was produced.

### <Silver Halide Emulsion Layer>

The emulsion layer coating liquid A prepared as described above was coated (painted) on the undercoating layer to set the coated amounts of Ag and gelatin to 8.0 g/m² and 0.94 g/m², respectively.

### <Conductive Fine Particle-Containing Layer>

The conductive fine particle-containing layer was formed by coating the following Solution 6 in an amount of 10 ml/m² onto the above silver halide emulsion layer.

### Solution 6:

| | | |
|---|---|---|
| Water | 1,000 | ml |
| Gelatin | 15 | g |
| Sb-doped tin oxide (trade name: SN100P, manufactured by | 40 | g |
| Ishihara Sangyo Kaisha, Ltd.) | | |

The Sb-doped tin oxide is spherical conductive fine particles. An average particle size of the fine particles was in the range of 0.01 to 0.03 μm (primary particle size). A powder resistance was in the range of 1 to 5 Ωcm. A specific surface area (simple BET method) was in the range of from 70 to 80 m²/g. Furthermore, a surfactant, a preservative, and a pH adjustor were appropriately added thereto.

### <Adhesion-Providing Layer>

The following Solution 7 was coated in an amount of 10 ml/m² on the aforementioned silver halide emulsion layer and conductive fine particle layer, whereby the adhesion-providing layer was applied thereon.

### Solution 7:

| | | |
|---|---|---|
| Water | 1000 | ml |
| Gelatin | 15 | g |

Furthermore, a surfactant, a preservative, and a pH adjustor were appropriately added thereto.

The thus-obtained coating product was dried. The resultant was named Sample A.

In Sample A, the conductive fine particles were contained in the conductive fine particle-containing layer in an amount of 0.4 g/m² and at a ratio by mass of the conductive fine particles to the binder of 2/1. In Sample A, the binder content in the conductive fine particle-containing layer and the layer above the conductive fine particle-containing layer was 0.3 g/m². In order to examine the resistivity of the conductive fine particles alone (the conductive film resistivity), the Sample A was subjected only to fixing treatment without being subjected to exposing/developing treatment. Thereafter, the surface resistivity excluding that of the silver halide was measured. As a result, it was 1×10⁹Ω/. Herein, the surface resistance was measured using a digital ultrahigh resistance/minute current-measuring instrument 8340A (trade name, manufactured by EDC CORPORATION).

### (Production of Inorganic EL Device Samples B to F)

Samples B to F were each produced in the same manner as sample A, except that the binder amount in both conductive fine particle-containing layer and layer above the conductive fine particle-containing layer was changed to 0.25, 0.2, 0.15, 0.1 and 0.05 g/m², respectively as shown in the following Table 1, by changing a coating amount of the above-described Solution 6 and Solution 7 and a gelatin amount.

### (Production of Inorganic EL Device Samples G to I for Comparison)

Samples G to I were each produced in the same manner as sample A, except that the conductive fine particle-containing layer was displaced to below the silver halide emulsion layer, and the binder amount in both conductive fine particle-containing layer and layer above the conductive fine particle-containing layer (including binder in the silver halide emulsion layer) was changed to 1.3, 1.0, 0.8 g/m², respectively, as shown in the following Table 1.

### (Production of Inorganic EL Device Sample N for Reference)

Sample N using ITO thin film as a conductive film was produced as a reference example. The used ITO is a product manufactured by Kitagawa Industries Co., LTD., having transmittance of 85% and haze of 1%.

### (Exposing/Developing Treatments)

Next, Samples A to I and N prepared as described above were each exposed to parallel light from a high-pressure mercury lamp as a light source through a lattice-form photomask capable of giving a developed silver image wherein lines and spaces were 5 μm and 595 respectively (a photomask wherein lines and spaces were 595 μm and 5 μm (pitch: 600 μm), respectively, and the spaces were in a lattice form). The resultant was developed with the following developing solution, subjected further to developing treatment by use of a fixing solution (trade name: N3X—R for CN16X, manufactured by FUJIFILM Corporation), and rinsed with pure water. In this way, Samples were obtained.

### [Composition of Developing Solution]

1 liter of the developing solution contained the following compounds:

| | |
|---|---|
| Hydroquinone | 0.037 mol/L |
| N-Methylaminophenol | 0.016 mol/L |
| Sodium metaborate | 0.140 mol/L |
| Sodium hydroxide | 0.360 mol/L |
| Sodium bromide | 0.031 mol/L |
| Potassium metabisulfite | 0.187 mol/L |

### (Preparation of Electroluminescent Elements)

Samples A to I and N produced as described above were each integrated into a dispersive inorganic EL (electroluminescent) element to make a light emission test as described below.

The EL Device was Produced as Follows:

A luminescent layer (light-emitting layer) containing phosphor particles having an average particle size of 50 to 60 μm was screen-printed on a transparent electrode, and dried at 110° C. for 1 hour using a blow-dryer. Thereafter, a reflection insulating layer containing pigments having an average particle size of 0.03 μm, and a back electrode containing carbon as a component were sequentially printed (coated) on the luminescent layer, and dried at 110° C. for 1 hour, to thereby produce the EL device. The size of the EL device was 5 cm×10 cm.

### (Evaluation)

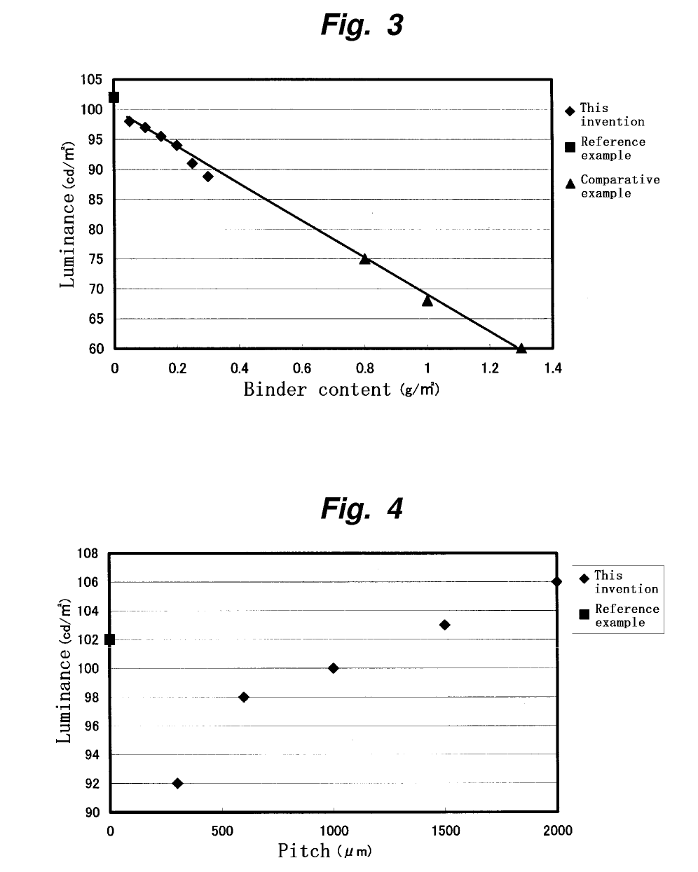

The power source used to measure the light-emitting luminance was a constant-frequency constant-voltage power source CVFT-D series (trade name, manufactured by Tokyo Seiden Co., Ltd.). The luminance was measured under the conditions of 100 V and 400 Hz using a luminance meter BM-9 (trade name, manufactured by TOPCON TECHNOHOUSE CORPORATION). The results obtained are shown in Table 1. A relation between an amount of the binder in the conductive particle-containing layer and luminance is shown in FIG. 3.

TABLE 1

| | | | Line (μm)/ | | |
|---|---|---|---|---|---|
| | Binder content | Pitch | Space | Luminance | |
| Sample | (g/m²) | (μm) | (μm) | (cd/m²) | Remarks |
| A | 0.3 | 600 | 5/595 | 88.8 | This |
| | | | | | invention |
| B | 0.25 | 600 | 5/595 | 91 | This |
| | | | | | invention |
| C | 0.2 | 600 | 5/595 | 94 | This |
| | | | | | invention |
| D | 0.15 | 600 | 5/595 | 95.5 | This |
| | | | | | invention |
| E | 0.1 | 600 | 5/595 | 97 | This |
| | | | | | invention |
| F | 0.05 | 600 | 5/595 | 98 | This |
| | | | | | invention |
| G | 1.3 | 600 | 5/595 | 60 | Comparative |
| | | | | | example |
| H | 1 | 600 | 5/595 | 68 | Comparative |
| | | | | | example |
| I | 0.8 | 600 | 5/595 | 75 | Comparative |
| | | | | | example |
| N | 0 | — | — | 102 | Reference |
| | | | | | example |

As shown in the results of Table 1 and FIG. 3, it is understood that samples A to F of the present invention, each of which was produced by the light-sensitive material having a binder amount of 0.05 to 0.5 g/m² in the conductive particle-containing layer and the layer above the conductive fine particle-containing layer, each showed higher luminance than those of samples G to I for comparison, each of which was produced by the light-sensitive material having a binder amount exceeding 0.5 g/m² in the conductive fine particle-containing layer and the layer above the conductive fine particle-containing layer. In particular, it is found that the smaller the content of a binder in the conductive fine particle-containing layer, the higher the luminance was. This reason is not certain. However, it is assumed that the binder in the conductive fine particle-containing layer becomes inhibitor of dielectric properties due to its low-dielectric constant, as a result, effective voltage applied to phosphors is reduced by the binder whereby luminance is reduced.

### Example 2

### Production of Inorganic EL Device Samples J to M

Samples J to M were produced in the same manner as production of the sample A in Example 1, except that the content of the binder in the conductive fine particle-containing layer and the layer above the conductive fine particle-containing layer was changed to 0.05 g/m². These samples were subjected to exposure and developing process in the same manner as in Example 1, except that the mesh pitch during exposure was changed to 300, 1,000, 1,500 or 2,000 μm as shown in Table 2.

### (Preparation of Electroluminescent Elements)

In the same manner as in Example 1, the thus-produced samples J to M and the reference sample N were each built into a dispersion type inorganic EL device, and a luminescent test was conducted using the device. The results are shown in Table 2. A relation between the mesh pitch and the luminance on the basis of the results of Table 2 is shown in FIG. 4.

TABLE 2

| | Binder content | Pitch | Line(μm)/ | Luminance | |
|---|---|---|---|---|---|
| Sample | (g/m²) | (μm) | Space (μm) | (cd/m²) | Remarks |
| J | 0.05 | 300 | 5/295 | 92 | This |
| | | | | | invention |
| K | 0.05 | 1000 | 5/995 | 100 | This |
| | | | | | invention |
| L | 0.05 | 1500 | 5/1495 | 103 | This |
| | | | | | invention |
| M | 0.05 | 2000 | 5/1995 | 106 | This |
| | | | | | invention |
| N | 0 | — | — | 102 | Reference |
| | | | | | example |

As shown in the results of Table 2 and FIG. 4, it is understood that each of samples J to M of the present invention, obtained from the light-sensitive material in which the content of the binder in the conductive fine particle-containing layer and the layer above the conductive fine particle-containing layer was 0.05 g/m², showed luminance equal to that of the reference sample N in which an ITO thin film was used as a conductive film. Further, it is understood that samples L and M of the present invention each having a broadened width of the opening portion (space) of the mesh pattern due to a broadened mesh pitch each show higher luminance than that of the reference sample N in which an ITO thin film was used as a conductive film.

### Example 3

### Production of Inorganic EL Device Samples O to T

Samples O to T were produced in the same manner as production of the sample A in Example 1, except that the content of the binder in the conductive fine particle-containing layer and the layer above the conductive fine particle-containing layer was changed to 0.05 g/m², and the addition amount of the conductive fine particles was changed so that the surface resistance of the conductive fine particle-containing layer was changed to 1×10⁸, 1×10⁹, 1×10¹°, 1×10¹¹,1×10¹² or 1×10¹³Ω/□. These samples were each subjected to exposure and developing process in a similar way as Example 1 except that the mesh pitch at the time of exposure was changed to 300, 600, 1,000 or 2,000 μm (mesh resistance: 30Ω/□, 80Ω/□, 130Ω/□, or 250Ω/□), as shown in Table 3. In the case where the mesh pitch was 600 μm, during exposure, a photomask having a grid-shaped photomask line/space of 595 μm/5 μm capable of providing a developed silver image of line/space of 5 μm/595 μm was used. Likewise, photomasks each having a grid-shaped space capable of providing a developed silver image in correspondence to various mesh pitches were used.

### (Preparation of Electroluminescent Elements)

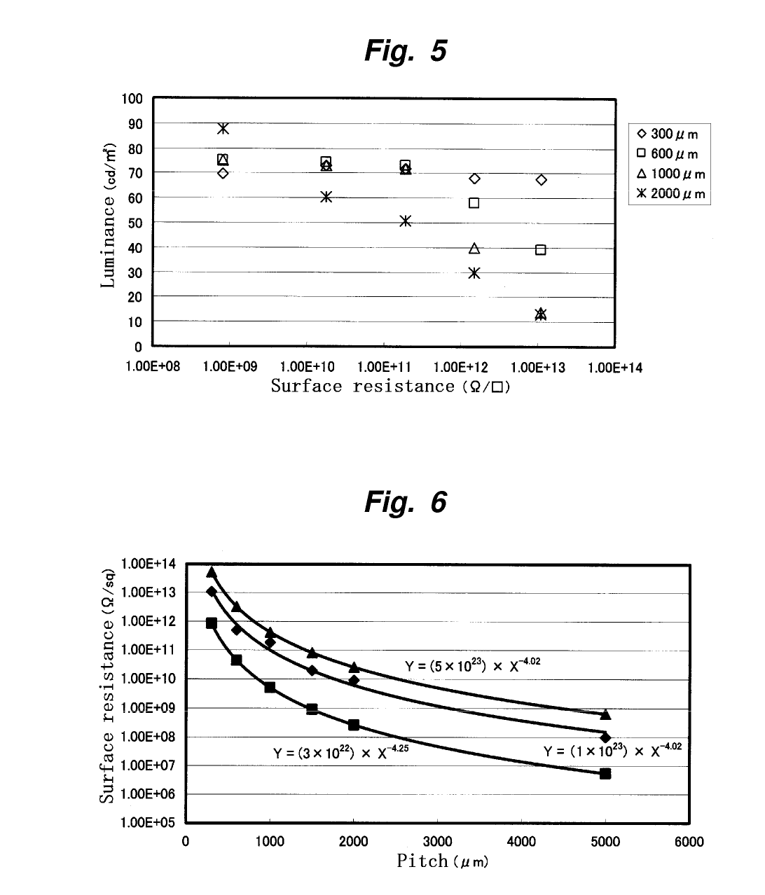

Samples O to T produced as described above were each integrated into a dispersive inorganic EL (electroluminescent) element to make a light emission test in a similar way as Example 1. The results are shown in Table 3. FIG. 5 shows the relationship between the surface resistivity of the conductive fine particle-containing layer (at the opening portion of the mesh pattern) and the luminance on the basis of the results of a light emission test conducted in the same manner as the above light emission test. Further, a relation between the width of the opening portion of the mesh pattern and the surface resistance of the opening portion of the mesh pattern for achieving high luminance is shown in FIG. 6. For example, term “1.00E+10” in FIGS. 5 and 6 represents “1.00×10¹⁰”.

Herein, the surface resistance of the opening portion was measured using a digital ultrahigh resistance/minute current-measuring instrument 8340A (trade name, manufactured by EDC CORPORATION).

TABLE 3

| | | Mesh pitch (Mesh resistance) | | | |
|---|---|---|---|---|---|
| Sam- | Surface resistivity | 300 μm | 600 μm | 1000 μm | 2000 μm |
| ple | at opening portion | (30 Ω/□) | (80 Ω/□) | (130 Ω/□) | (250 Ω/□) |
| O | 1.0 × 10⁸ Ω/□ | 67.8 | 75.2 | 75.2 | 85.9 |
| P | 1.0 × 10⁹ Ω/□ | 70.1 | 76.3 | 73 | 60.7 |
| Q | 1.0 × 10¹⁰ Ω/□ | 71.3 | 76 | 76.4 | 50 |
| R | 1.0 × 10¹¹ Ω/□ | 68.1 | 75.9 | 71.9 | 40.5 |
| S | 1.0 × 10¹² Ω/□ | 69.7 | 50.1 | 40.5 | 28.5 |
| T | 1.0 × 10¹³ Ω/□ | 60 | 39.2 | 13.72 | 12.93 |

(Unit: cd/m²)

As shown in the results of Table 3 and FIG. 5, it is understood that when the mesh pitch was 300 μm, even though conductivity was reduced until the surface resistance was increased up to 10¹³Ω/□, light was sufficiently emitted. Whereas, when the mesh pitch is 2,000 μm, if conductivity is excessively reduced, luminance was not sufficiently emitted.

In view of these results, it is considered that when the pitch is narrow, the width of the conductive portion (metal silver portion) is also narrow, and therefore even though the resistance of the opening portion is high, voltage can be applied to phosphors whereby light is emitted. In contrast, when the pitch is broad and the resistance of the opening portion is high, voltage cannot be sufficiently applied to phosphors, which results in difficulty in emission of light.

Further, by adjusting the content of conductive fine particles, the pitch and the surface resistance of the opening portion were changed as shown in Table 4 to produce inorganic EL devices. From the results of light-emission test, it is found that these devices also each showed luminance of 60 cd/m² or more which is enough to a practical use. Further, also in these tests, it is found that there is the same tendency as the results of evaluation described in Table 3.

From the above results, it found that, as shown in FIG. 6, an EL device showing luminance of 60 cd/m² or more is effectively obtained when the width X (μm) of an opening portion of the mesh pattern of the conductive layer and the surface resistance Y (Ω/□) of the opening portion of the mesh pattern meet the following formulae (a) and (b).

50≦X≦7000 (a)

10⁵≦Y≦(5×10²³)×X^{-4.02} (b)

Further, when the Y meets the following formula (b1), an EL device showing higher luminance is effectively obtained, and when the Y meets the following formula (b2), an EL device showing further higher luminance is effectively obtained (FIG. 6).

10⁵≦Y≦(1×10²³)×X^{-4.02} (b1)

10⁵≦Y≦(3×10²²)×X^{-4.25} (b2)

TABLE 4

| | Surface resistivity at | Surface resistivity at |
|---|---|---|
| Pitch (μm) | opening portion (Ω/□) | opening portion (Ω/□) |
| 300 | 1.09 × 10¹³ | 5.36 × 10¹³ |
| 600 | 5.00 × 10¹¹ | 3.29 × 10¹² |
| 1000 | 1.87 × 10¹¹ | 4.22 × 10¹¹ |
| 1500 | 2.00 × 10¹⁰ | 8.24 × 10¹⁰ |
| 2000 | 9.14 × 10⁹ | 2.59 × 10¹⁰ |
| 5000 | 1.00 × 10⁸ | 6.48 × 10⁸ |

Having described our invention as related to the present embodiments, it is our intention that the present invention not be limited by any of the details of the description, unless otherwise specified, but rather be construed broadly within its spirit and scope as set out in the accompanying claims.

### DESCRIPTION OF SYMBOLS

1 Inorganic EL device
2 Transparent electrode (Transparent conductive film)
3 Phosphor layer (Phosphor particles layer)
4 Reflection insulating layer (Dielectric layer)
5 Back electrode
6, 7 electrode
8 Silver paste (Supplemental electrode)
9 Insulating paste
21 Transparent support
22 Undercoat layer (Gel layer)
23 Conductive fine particle-containing layer (Tin oxide layer)
24 Conductive layer (Silver mesh pattern)
25 Colloidal silica particle
31 Phosphor particle

What is claimed is:

1. An EL device, comprising:
a support,
a conductive layer with a mesh pattern,
a phosphor layer,
a reflection insulating layer, and
a back electrode;
wherein the conductive layer, the phosphor layer, the reflection insulating layer and the back electrode are provided on the support in this order, and
wherein a width X (μm) of an opening portion of the mesh pattern of the conductive layer and a surface resistance Y (Ω/□) of the opening portion of the mesh pattern of the conductive layer meet the following formulae (a) and (b).
50≦X≦7000 (a)
10⁵≦Y≦(5×10²³)×X^{-4.02} (b)

2. The EL device according to claim 1, wherein the width X of the opening portion of the mesh pattern of the conductive layer is from 100 to 5000 μm.

3. The EL device according to claim 1, wherein the surface resistance Y of the opening portion of the mesh pattern of the conductive layer is from 10⁶ to 10¹⁵Ω/□.

4. The EL device according to claim 1, wherein the opening portion of the mesh pattern of the conductive layer contains conductive fine particles.

5. The EL device according to claim 4, wherein the conductive fine particles are antimony-doped tin oxide.

6. The EL device according to claim 4, wherein the opening portion of the mesh pattern of the conductive layer contains the conductive fine particles and a binder in a ratio by mass of 1/33 to 5/1.

7. The EL device according to claim 6, wherein the opening portion of the mesh pattern of the conductive layer contains the conductive fine particles and the binder in a ratio by mass of 1/3 to 5/1.

8. A conductive film, comprising:
a support, and
a conductive layer with a mesh pattern provided on the support;
wherein a width X (μm) of an opening portion of the mesh pattern of the conductive layer and a surface resistance Y (Ω/□) of the opening portion of the mesh pattern of the conductive layer meet the following formulae (a) and (b).
50≦X≦7000 (a)
10⁵≦Y≦(5×10²³)×X^{-4.02} (b)

9. A light-sensitive material for forming a conductive film, comprising:
a support, and
a silver salt-containing emulsion layer on the support;
wherein at least one of the silver salt-containing emulsion layer and any other layers at the silver salt-containing emulsion layer side contains conductive fine particles and a binder, and
wherein a content of the binder in the layer containing conductive fine particles and a binder is from 0.05 to 0.5 g/m².

10. The light-sensitive material for forming a conductive film according to claim 9, wherein the content of the binder is from 0.05 to 0.2 g/m².

11. The light-sensitive material for forming a conductive film according to claim 9, wherein a content of the conductive fine particles is from 0.05 to 1 g/m².

12. The light-sensitive material for forming a conductive film according to claim 11, wherein the content of the conductive fine particles is from 0.1 to 0.5 g/m².

13. The light-sensitive material for forming a conductive film according to claim 9, wherein colloidal silica is contained in an amount of 0.05 to 0.5 g/m² in the at least one of the silver salt-containing emulsion layer and any other layers at the silver salt-containing emulsion layer side.

14. A conductive film comprising a conductive portion formed by subjecting the light-sensitive material for forming a conductive film according to claim 9 to pattern-exposure and developing process.
